(19) United States
(12) Patent Application Publication
(10) Pub. No.: US 2019/0074348 A1
(43) Pub. Date: Mar. 7, 2019

(54) CAPACITOR

(71) Applicant: Murata Manufacturing Co., Ltd., Nagaokakyo-shi (JP)

(72) Inventors: Nobuhiro Ishida, Nagaokakyo-shi (JP); Junko Izumitani, Nagaokakyo-shi (JP); Masatomi Harada, Nagaokakyo-shi (JP); Takeshi Kagawa, Nagaokakyo-shi (JP)

(21) Appl. No.: 16/180,577

(22) Filed: Nov. 5, 2018

Related U.S. Application Data
(63) Continuation of application No. PCT/JP2017/024455, filed on Jul. 4, 2017.

(30) Foreign Application Priority Data
Jul. 7, 2016 (JP) 2016-135127

(51) Int. Cl. H01L 49/02

(52) U.S. Cl. CPC H01L 28/75

(57) ABSTRACT

A capacitor that includes a substrate; a lower electrode formed on the substrate, and including an upper surface, a lower surface and an end surface that connects the upper surface and the lower surface. Moreover, the capacitor includes a dielectric film formed on the lower electrode; an upper electrode formed on the dielectric film; and a terminal electrode connected to the upper electrode. Furthermore, the upper surface of the lower electrode is formed in a region on an inner side of a periphery of the lower surface of the lower electrode with at least part of the end surface being a tapered shape.

### CROSS REFERENCE TO RELATED APPLICATIONS

The present application is a continuation of PCT/JP2017/024455 filed Jul. 4, 2017, which claims priority to Japanese Patent Application No. 2016-135127, filed Jul. 7, 2016, the entire contents of each of which are incorporated herein by reference.

### TECHNICAL FIELD

The present disclosure relates generally to a capacitor.

### BACKGROUND

MIM (Metal Insulator Metal) capacitors are generally well known as typical capacitor elements that can be used for a semiconductor integrated circuit. The MIM capacitor is a capacitor that includes a parallel-plate structure which sandwiches a dielectric body between a lower electrode and an upper electrode.

For example, Patent Document 1 (identified below) discloses such a capacitor. The capacitor described in Patent Document 1 includes an underlayer electrode, a dielectric layer that is formed on the underlayer electrode, an upper electrode layer which is formed on the dielectric layer, and a terminal electrode which is connected to the upper electrode layer.

Patent Document 1: Japanese Patent Application Laid-Open No. 2015-216246.

For example, it is demanded that a capacitor that is used for a high frequency impedance matching element and has a capacitance value: approximately 0.1 to several 10 pF is formed at a narrow deviation such as a target capacitance value: ±0.05 pF. To precisely form the capacitor at a target capacitance value, it is necessary to precisely form an MIM portion (intrinsic capacitance) which sandwiches the dielectric layer between the lower electrode and the upper electrode, and, in addition, decrease a stray capacitance generated by sandwiching an interlayer film between the lower electrode and the terminal electrode connected to the upper electrode layer. In this regard, when a facing area of the lower electrode and the terminal electrode is S, an interlayer distance is d and a dielectric constant of an interlayer insulation film is ε, a stray capacitance C generated between the lower electrode and the terminal electrode can be expressed as C=6×S/d. Both of a cross section of the lower electrode and a cross section of the terminal electrode of the above conventional thin film capacitor are formed in rectangular shapes, and therefore the facing area S is relatively large. Furthermore, to realize a lower profile of an element, it is necessary to shorten the interlayer distance d. When the interlayer distance d is short, if d varies, the stray capacitance C significantly varies.

In view of the above, the relatively high stray capacitance C having a variation is generated between the lower electrode and the terminal electrode. When the stray capacitance is parasitic in parallel on the MIM portion (intrinsic capacitance). Therefore, there is a problem that, when the relatively high stray capacitance C is generated, even if the MIM portion (intrinsic capacitance) is precisely formed, a capacitance value deviates from the target capacitance value, and a narrower deviation cannot be realized.

### SUMMARY OF THE INVENTION

The present disclosure has been made in light of such a situation. An object of the present disclosure is to provide a capacitor that reduces a stray capacitance generated between a lower electrode and a terminal electrode.

Thus, a capacitor according to an exemplary aspect of the present disclosure includes a substrate; a lower electrode formed on the substrate and with an upper surface, a lower surface and an end surface that connects the upper surface and the lower surface; a dielectric film formed on the lower electrode; an upper electrode formed on the dielectric film; and a terminal electrode connected to the upper electrode. Moreover, at least part of the upper surface of the lower electrode is formed in a region on an inner side of a periphery of the lower surface of the lower electrode in a plan view of the lower electrode seen from the terminal electrode, and at least part of the end surface has a tapered shape.

According to the exemplary embodiment of the present disclosure, a capacitor is provided that reduces a stray capacitance generated between a lower electrode and a terminal electrode.

### BRIEF DESCRIPTION OF THE DRAWINGS

FIG. 1 is a plan view schematically illustrating a structure of a capacitor 10 according to a first exemplary embodiment.

FIG. 2 is a view illustrating an AA′ cross section of FIG. 1.

FIG. 3 is a view illustrating a comparative example of the capacitor 10 according to the first exemplary embodiment.

FIG. 4A is a view illustrating a process of a method for manufacturing the capacitor 10 according to the first exemplary embodiment.

FIG. 4B is a view illustrating the process of the method for manufacturing the capacitor 10 according to the first exemplary embodiment.

FIG. 4C is a view illustrating the process of the method for manufacturing the capacitor 10 according to the first exemplary embodiment.

FIG. 4D is a view illustrating the process of the method for manufacturing the capacitor 10 according to the first exemplary embodiment.

FIG. 4E is a view illustrating the process of the method for manufacturing the capacitor 10 according to the first exemplary embodiment.

FIG. 4F is a view illustrating the process of the method for manufacturing the capacitor 10 according to the first exemplary embodiment.

FIG. 4G is a view illustrating the process of the method for manufacturing the capacitor 10 according to the first exemplary embodiment.

FIG. 4H is a view illustrating the process of the method for manufacturing the capacitor 10 according to the first exemplary embodiment.

FIG. 5 is a cross-sectional view schematically illustrating a structure of the capacitor 10 according to a second exemplary embodiment.

FIG. 6 is a cross-sectional view schematically illustrating a structure of the capacitor 10 according to a third exemplary embodiment.

### DETAILED DESCRIPTION

Hereinafter, exemplary embodiments of the present invention will be described with reference to the accompanying drawings.

### 1. First Exemplary Embodiment

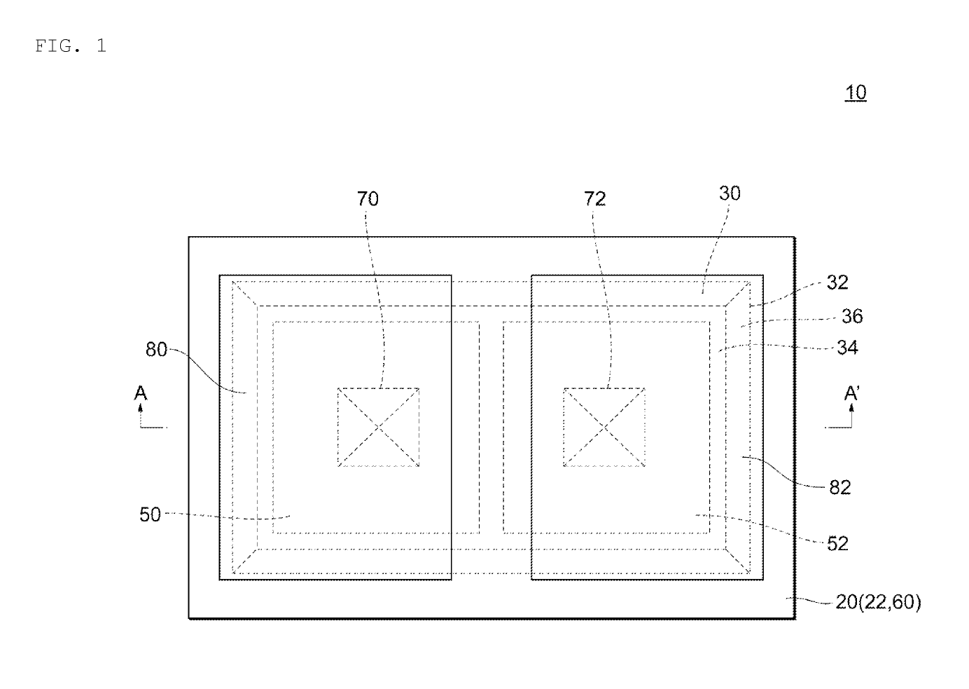

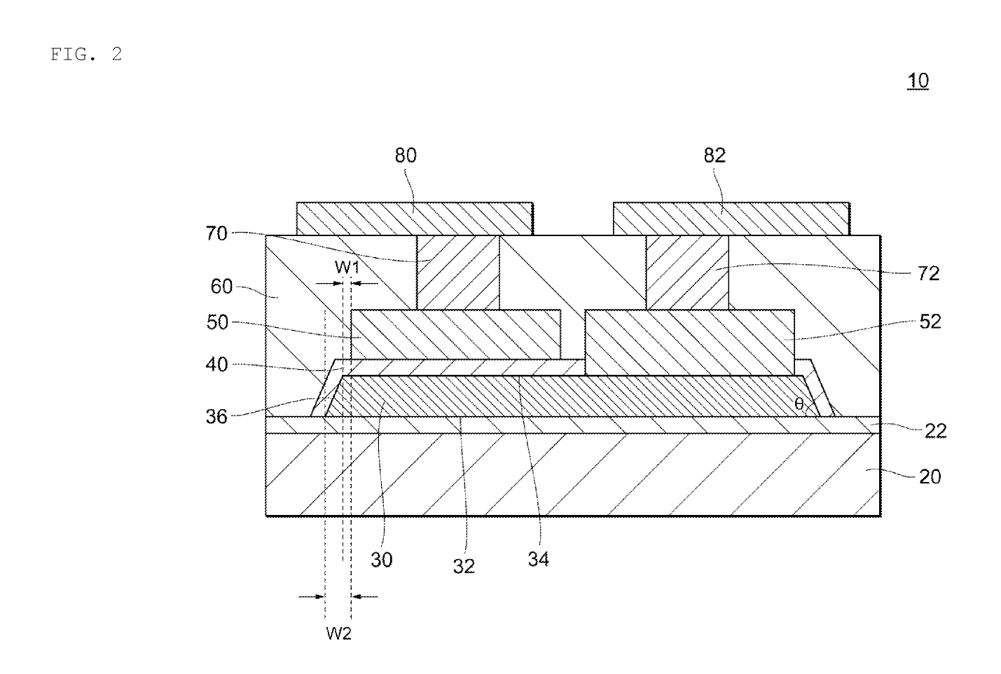

FIG. 1 is a plan view schematically illustrating a structure of a capacitor 10 according to the first exemplary embodiment. Furthermore, FIG. 2 is a view illustrating an AA′ cross section of FIG. 1. In addition, FIGS. 1 and 2 illustrate extracted necessary components for explaining at least part of features of the structure of the capacitor 10, yet do not prevent the capacitor 10 from including unillustrated components.

The capacitor 10 employs a configuration including a substrate 20, a lower electrode 30, a dielectric film 40, and an upper electrode 50. Furthermore, the capacitor 10 includes a via electrode 70 and a terminal electrode 80 which are electrically connected to the upper electrode 50, and a contact electrode 52, a via electrode 72 and a terminal electrode 82 which are electrically connected with the lower electrode 30.

As further shown, the substrate 20 has a rectangular shape in a plan view (FIG. 1) of the capacitor 10 seen from the terminal electrode 80 toward the substrate 20. The substrate 20 is a semiconductor substrate such as silicon. According to an exemplary aspect, the length of the long side of the substrate 20 is 200 μm or more and 600 μm or less, and the length of a short side is 100 μm or more and 300 μm or less, for example. The capacitor 10 includes an insulation film 22 such as a silicon oxide on the surface of the substrate 20. The insulation film 22 is formed by a material which closely contacts the substrate 20 formed below the insulation film 22, and the lower electrode 30 formed on the insulation film 22. The insulation film 22 may be a film including a plurality of layers formed by different materials. The insulation film 22 only needs to electrically insulate the substrate 20 and the lower electrode 30, and a film thickness is preferably approximately 0.5 μm or more and 3 μm or less. Furthermore, the substrate 20 may be formed by an insulation material, such as alumina, for example. In this case, the insulation film 22 may not be formed on the substrate 20.

The lower electrode 30 is formed on an upper layer of the substrate 20 and in a region on an inner side of a periphery of the substrate 20 in the plan view. The lower electrode 30 is preferably formed on the inner side which is approximately 5 μm or more and 30 μm or less from an end portion of the periphery of the substrate 20. The lower electrode 30 includes a lower surface 32 which is in contact with the insulation film 22, an upper surface 34 which is in contact with the dielectric film 40, and an end surface 36 which connects the lower surface 32 and the upper surface 34. The film thickness of the lower electrode 30 is preferably thick to reduce a series resistance. More specifically, the film thickness of the lower electrode 30 is preferably 0.3 μm or more and 10 μm or less, and is more preferably 0.5 μm or more and 5 μm or less, for example.

The lower surface 32 and the upper surface 34 of the lower electrode 30 have rectangular shapes. Furthermore, the upper surface 34 is formed in a region on the inner side of a periphery of the lower surface 32 in the plan view. The end surface 36 is formed obliquely with respect to the lower surface 32 or the upper surface 34 to connect the lower surface 32 and the upper surface 34. That is, the end surface 36 has such a tapered shape that the area (the width in the cross section) of the lower electrode 30 in the plan view becomes gradually smaller from the lower surface 32 to the upper surface 34. Moreover, an angle θ formed between the lower surface 32 and the end surface 36 is preferably 30° or more and 60° or less, and is more preferably 40° or more and 50° or less. When the angle θ is smaller than 30°, it is difficult to control the shape of the end surface 36. When the angle θ is larger than 60°, an effect of reduction of the stray capacitance is small. When, for example, the film thickness of the lower electrode is 5 μm, θ=45° holds and W2=10 μm holds, W1=5 μm holds. When the stray capacitance generated between the lower electrode and the terminal electrode is substantially proportional to facing electrode widths. Consequently, it is possible to reduce the stray capacitance by 50% or more by forming the end surface 36 in the tapered shape.

In the present embodiment, the lower electrode 30 has a rectangular shape in the plan view, and the end surface 36 obliquely inclines. First of all, regarding the end surface 36 of the lower electrode 30, at least the end surface 36 which overlaps the terminal electrode 80 in the plan view only needs to be formed obliquely with respect to the lower surface 32 or the upper surface 34. Furthermore, the end surface 36 may be formed in a stepwise shape.

The lower electrode 30 is preferably a metal made of Cu, Ag, Au, Al, Ni, Cr, or Ti or a conductor including these metals, for example. The lower electrode 30 may be formed to include a plurality of layers formed by different materials.

As further shown, the dielectric film 40 is formed to cover the surface of the lower electrode 30. More specifically, the dielectric film 40 is formed to cover the upper surface 34 and the end surface 36 of the lower electrode 30, and includes an opening through which the lower electrode 30 is exposed at a position at which the contact electrode 52 is formed. The dielectric film 40 is formed by a material such as an oxide or a nitride such as SiO₂, SiN, Al₂O₃, HfO₂, Ta₂O₅ or ZrO₂ having dielectricity or an insulation property. The film thickness of the dielectric film 40 is preferably 0.02 μm or more and 2 μm or less.

The upper electrode 50 is formed on the dielectric film 40 and on the inner side of a periphery of the upper surface 34 of the lower electrode 30 in the plan view. Furthermore, the upper electrode 50 is formed in part of a region of the upper surface 34 of the lower electrode 30. The film thickness of the upper electrode 50 is preferably thick to reduce a series resistance. More specifically, the film thickness of the upper electrode 50 is preferably 0.3 μm or more and 10 μm or less, and is more preferably 0.5 μm or more and 5 μm or less.

The contact electrode 52 is an electrode which is electrically connected to the lower electrode 30. The contact electrode 52 is formed in a region other than the part of the region in which the upper electrode 50 is formed on the upper surface 34 of the lower electrode 30. Furthermore, the contact electrode 52 is formed to fill an opening formed in the dielectric film 40. That is, the contact electrode 52 is formed to contact the lower electrode 30 inside the opening. Furthermore, the contact electrode 52 may be formed from the inside of the opening to an upper side of the dielectric film 40 around the opening.

In the present embodiment, the upper electrode 50 and the contact electrode 52 are formed by the same material. The upper electrode 50 and the contact electrode 52 are preferably a metal made of Cu, Ag, Au, Al, Ni, Cr, or Ti or a conductor including these metals.

The protection film 60 is formed to cover the upper electrode 50 and the contact electrode 52. Furthermore, the protection film 60 includes openings through which the upper electrode 50 and the contact electrode 52 are exposed at positions at which the via electrodes 70 and 72 are formed. Furthermore, the protection film 60 is formed to cover the dielectric film 40 and the insulation film 22 at an end portion of the substrate 20. The protection film 60 may be formed in a region on the inner side of the periphery of the substrate 20 in the plan view. Furthermore, the protection film 60 is formed by an insulation material such as a polyimide resin or a silicon oxide. The film thickness of the protection film 60 is preferably 1 μm or more and 20 μm or less.

The via electrodes 70 and 72 are electrodes which electrically connect the upper electrode 50 and the terminal electrode 80, and the contact electrode 52 and the terminal electrode 82, respectively. The via electrodes 70 and 72 are formed to fill the opening formed in the protection film 60. In addition, the via electrodes 70 and 72 may be formed integrally with the terminal electrodes 80 and 82 described below.

The terminal electrode 80 is a terminal which is formed on the protection film 60 and the via electrode 70, and electrically connects the upper electrode 50 and the outside. In the present embodiment, the end surface of the terminal electrode 80 is formed on an outer side of the periphery of the upper surface 34 of the lower electrode 30.

In addition, the terminal electrode 82 is a terminal which is formed on the protection film 60 and the via electrode 72, and electrically connects the lower electrode 30 and the outside. Although the terminal electrode 82 has a rectangular shape in the plan view, unlike the terminal electrode 80, at least one end surface may not be necessarily formed on the outer side of the periphery of the upper electrode 50 to overlap the lower electrode 30 in an exemplary aspect. The terminal electrode 80 and the terminal electrode 82 are preferably materials having lower resistivity than those of the lower electrode 30 and the upper electrode 50, and is preferably a metal made of Cu or Al. This is because it is possible to further reduce a resistance. Furthermore, the outermost surface of the terminal electrode 7 may be Au or Sn. The film thicknesses of the terminal electrode 80 and the terminal electrode 82 are preferably 1 μm or more and 10 μm or less.

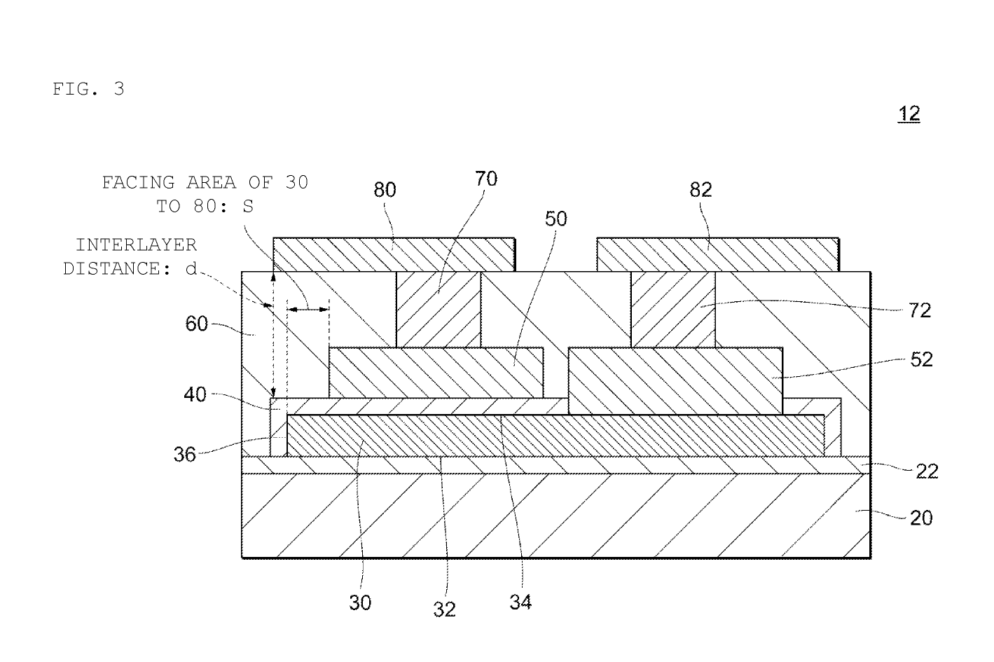

FIG. 3 is a view illustrating a comparative example of the capacitor 10 according to the present embodiment. A capacitor 12 according to this comparative example includes the end surface 36 of the lower electrode 30 formed vertically with respect to the lower surface 32 of the lower electrode 30. A function and an effect of the capacitor 10 according to the first embodiment will be described by using the capacitor 12 according to this comparative example.

According to the capacitor 12 according to the comparative example, an angle formed between the upper surface 34 and the end surface 36 of the lower electrode 30 is a right angle, and the upper surface 34 of the lower electrode 30 faces the lower surface of the terminal electrode 80 (a surface which is in contact with the protection film 60) with the dielectric film 40 and the protection film 60 interposed therebetween.

As described above, the capacitor 12 according to the comparative example has a relatively large area (i.e., the area of a region S) of facing surfaces of the lower electrode 30 and the terminal electrode 80.Therefore, a multilayer structure of the lower electrode 30, the dielectric film 40, the protection film 60, and the terminal electrode 80 forms a relatively high stray capacitance. Hence, in the capacitor 12, the stray capacitance is formed in parallel to a capacitance (intrinsic capacitance) formed by the lower electrode 30 and the upper electrode 50. Therefore, even when the intrinsic capacitance is precisely formed, a capacitance value deviates from the target capacitance value.

On the other hand, the capacitor 10 according to the present embodiment is formed such that the end surface 36 of the lower electrode 30 has the tapered shape as described above. Consequently, it is possible to reduce the area of the facing surfaces of the upper surface 34 of the lower electrode 30 facing the lower surface of the terminal electrode 80. Advantageously, it is possible to reduce the stray capacitance formed by the lower electrode 30 and the terminal electrode 80, so that only an intrinsic capacitance component determines the capacitance value of the capacitor 10, and it is possible to form the capacitor at the target capacitance value.

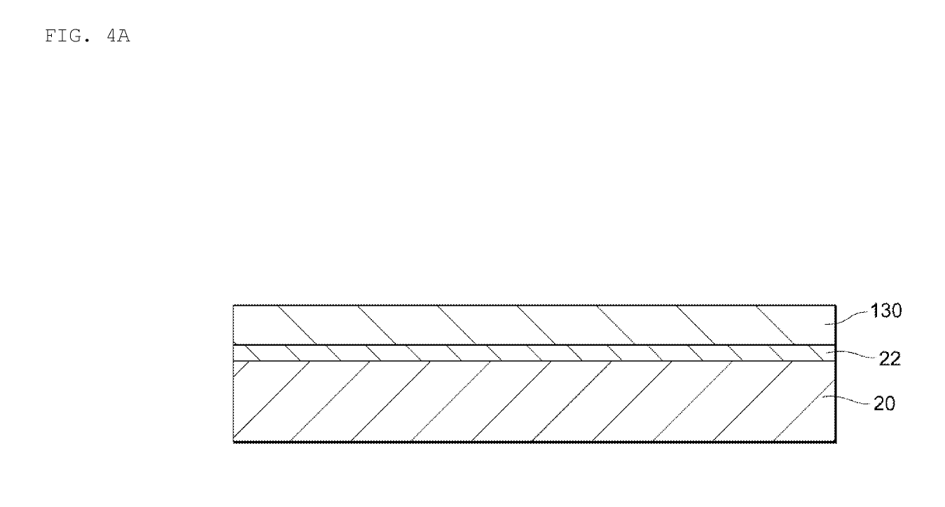

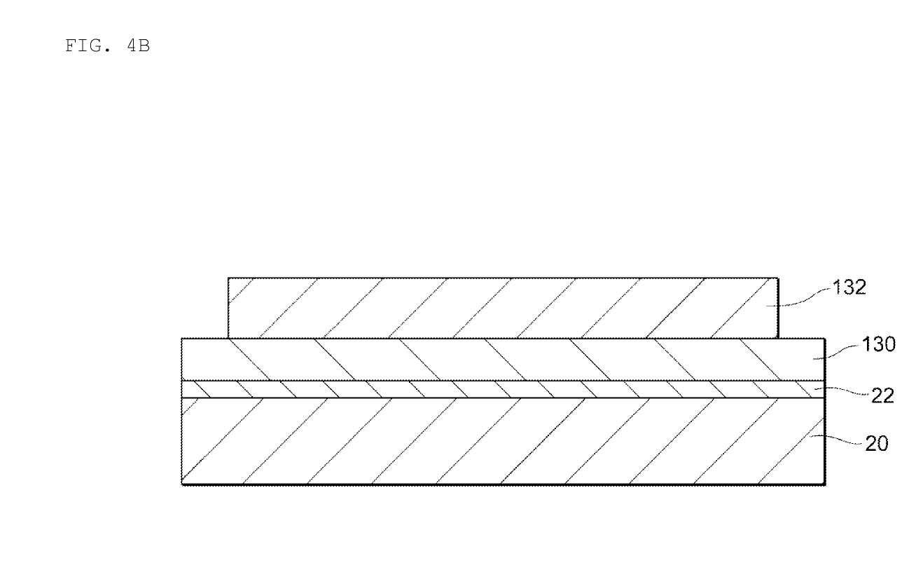

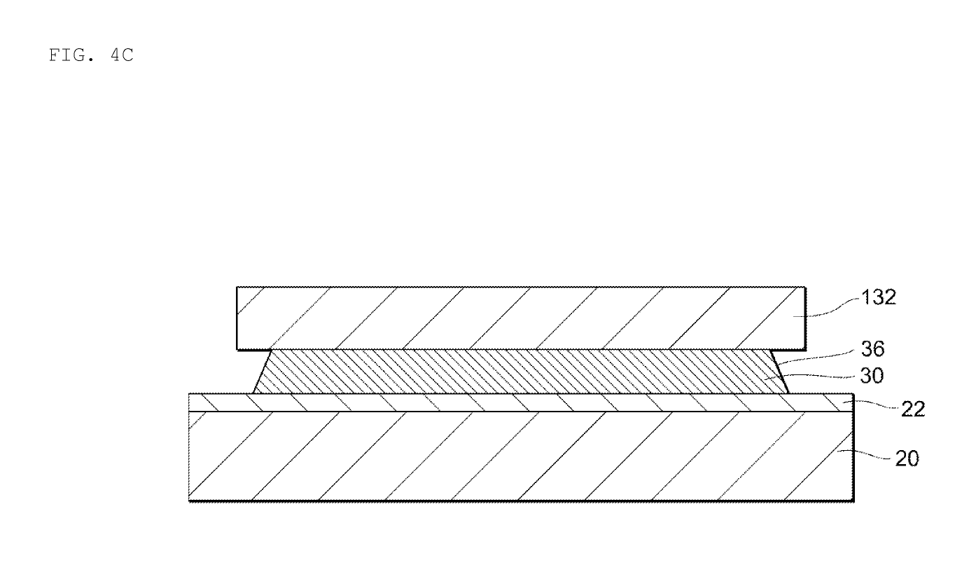

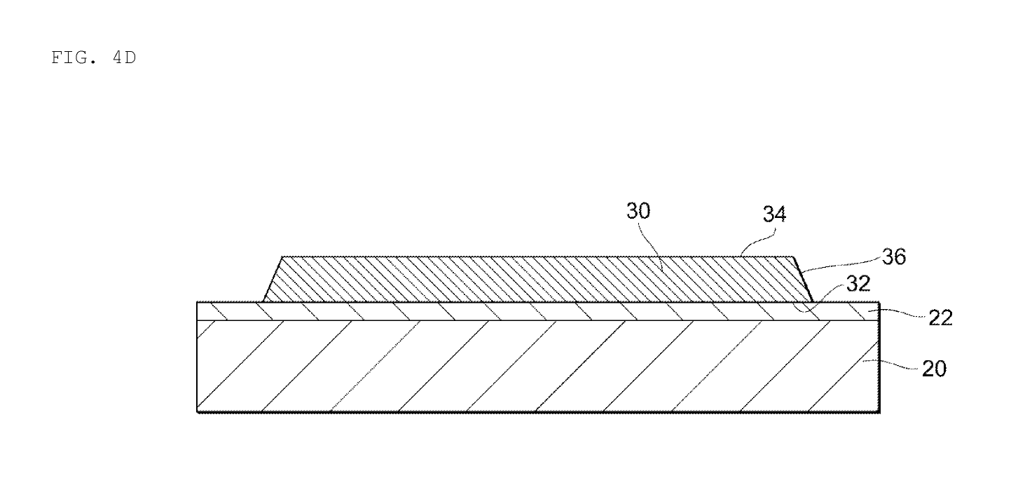

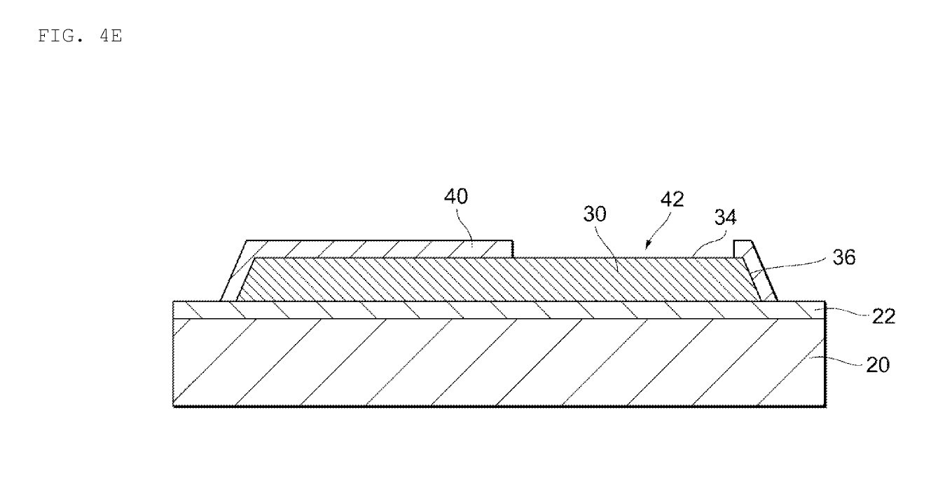

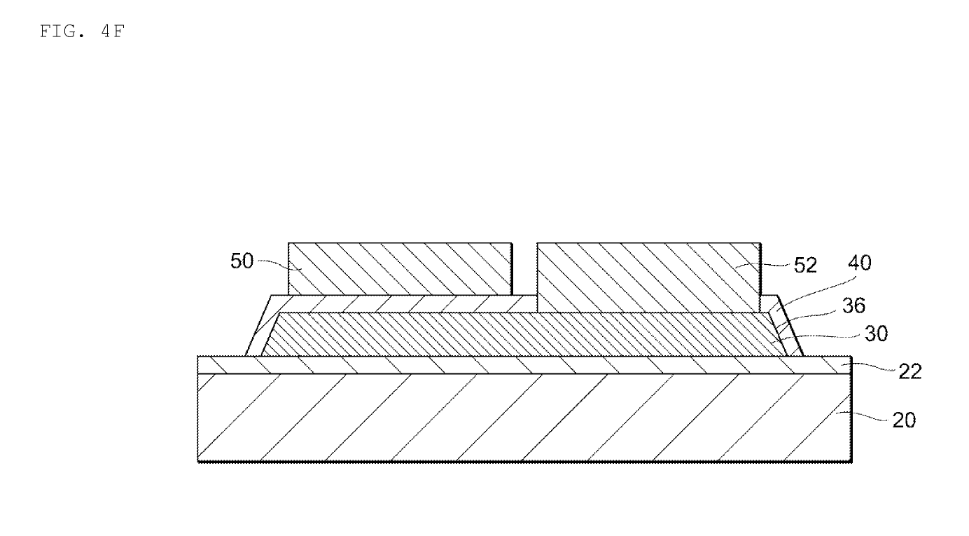

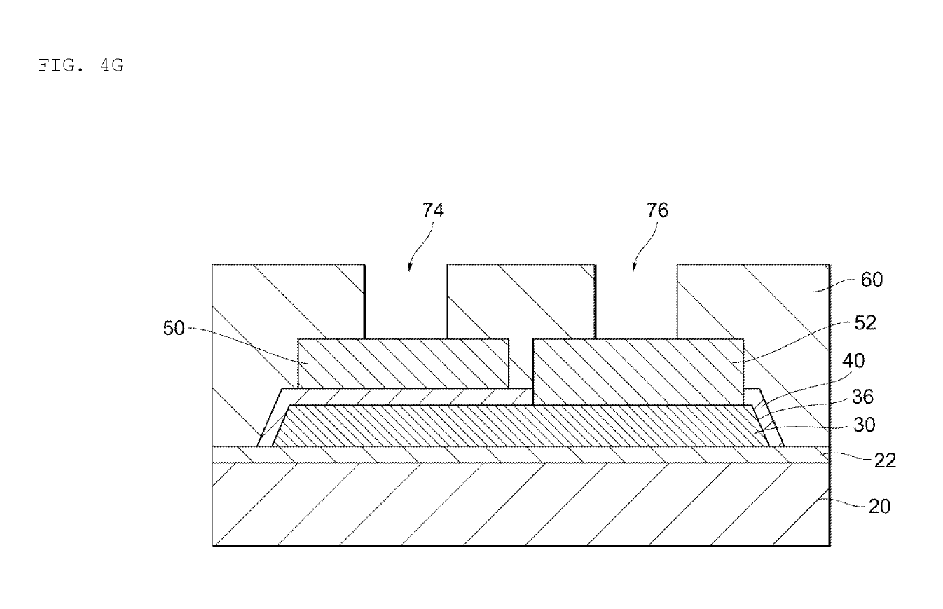

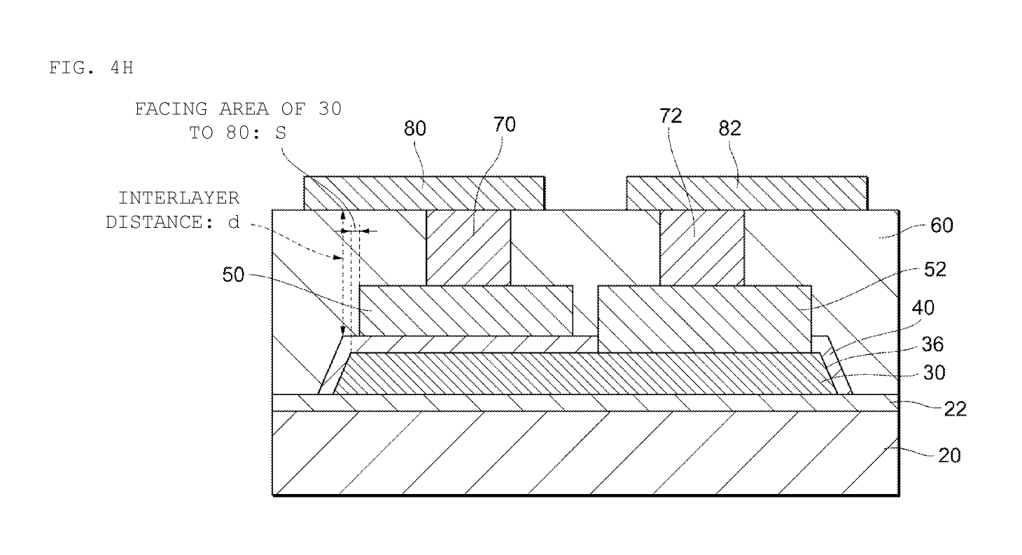

FIGS. 4A to 4H are schematic views illustrating an example of a method for manufacturing the capacitor 10 according to an exemplary embodiment. The method for manufacturing the capacitor 10 will be described below with reference to FIGS. 4A to 4H. In addition, the one capacitor 10 will be described with reference to FIGS. 4A to 4H. However, a plurality of capacitors 10 can be simultaneously formed by using the same substrate.

As illustrated in FIG. 4A, the substrate 20 is prepared first to form the insulation film 22 on the substrate 20. For example, the substrate 20 is a silicon substrate, and the insulation film 22 is a silicon oxide film obtained by oxidizing the surface of the silicon substrate. The film thickness of the silicon oxide film is preferably 0.5 μm or more and 3 μm or less. Next, a metal film 130 which is made of a metal material which forms the lower electrode 30 is formed on the insulation film 22. More specifically, the film thickness of the metal film 130 is preferably 0.3 μm or more and 10 μm or less, and is more preferably 0.5 μm or more and 5 μm or less.

Next, as illustrated in FIG. 4B, a photoresist is applied on the metal film 130, and a resist mask 132 patterned in a shape of the lower electrode 30 is formed. Furthermore, the resist mask 132 is used as a mask to wet-etch the metal film 130. Then, the metal film 130 is gradually etched from an exposed region (a region which is not masked by the resist mask 132). Therefore, a portion of the metal film 130 close to the resist mask 132 is etched more than a portion close to the insulation film 22. Thus, as illustrated in FIG. 4C, the end surface 36 which is oblique with respect to a lower surface of the metal film 130 is formed.

Next, as illustrated in FIG. 4D, the resist mask 132 is removed. Thus, the lower electrode 30 including the lower surface 32, the upper surface 34 and the end surface 36 is formed.

Next, as illustrated in FIG. 4E, the dielectric film 40 is formed. First, a dielectric material which forms the dielectric film 40 is formed on the upper surface 34 and the end surface 36 of the lower electrode 30, and the insulation film 22. Preferably, the dielectric film 40 is a silicon nitride film, and has the film thickness which is 0.02 μm or more and 2 μm or less. Furthermore, the patterned photoresist is used as a mask to form the opening 42 by removing part of the dielectric material such that part of the upper surface 34 of the lower electrode 30 is exposed, and form the dielectric film 40.

In the present embodiment, the end surface 36 of the lower electrode 30 is formed to have the tapered shape, so that the dielectric material can be formed with a good coverage on the end surface 36 of the lower electrode 30. Consequently, it is possible to improve an insulation resistance of the dielectric film 40 on the end surface 36. Furthermore, the angle formed between the upper surface 34 and the end surface 36 of the lower electrode 30 is an obtuse angle. Consequently, it is possible to disperse the electric field generated at this angle.

Next, as illustrated in FIG. 4F, the upper electrode 50 and the contact electrode 52 are formed. First, the metal material which forms the upper electrode 50 and the contact electrode 52 is formed on the dielectric film 40, the insulation film 22, and in the opening 42 (see FIG. 4E) of the dielectric film 40. The film thickness of the upper electrode 50 is preferably thick to reduce the series resistance. The film thickness of the upper electrode 50 is preferably 0.3 μm or more and 10 μm or less, and is more preferably 0.5 μm or more and 5 μm or less. Furthermore, the metal material is etched by using the patterned photoresist as the mask to form the upper electrode 50 in part of the region of the lower electrode 30 and form the contact electrode 52 in the opening 42 of the dielectric film 40.

Next, as illustrated 4G, the protection film 60 is formed. First, the insulation material which forms the protection film 60 is formed on the upper electrode 50, the contact electrode 52, the dielectric film 40, and the insulation film 22. The protection film 60 is formed by the insulation material such as a polyimide resin or a silicon oxide. The film thickness of the protection film 60 is preferably 1 μm or more and 20 μm or less. Furthermore, the insulation material is etched by using the patterned photoresist as the mask to form the vias 74 and 76 such that part of the upper electrode 50 and part of the contact electrode 52 are exposed.

Next, as illustrated in FIG. 4H, the metal material is filled in the vias 74 and 76 (see FIG. 4G), and the via electrodes 70 and 72 are formed. Furthermore, the metal material is formed on the protection film 60 and the via electrodes 70 and 72, and is etched by using the patterned photoresist mask as the mask to form the terminal electrodes 80 and 82. According to the above process, the capacitor 10 according to the present embodiment can be obtained.

### 2. Second Exemplary Embodiment

Next, the capacitor 10 according to the second exemplary embodiment will be described. In the second embodiment and subsequent embodiments, matters common to those of the first embodiment will not be described, and only differences will be described. Particularly, the same function and effect of the same configuration will not be successively mentioned for each embodiment. Furthermore, components in the second embodiment assigned with the same reference numerals as those in the first embodiment will have the same configurations and functions as those in the first embodiment.

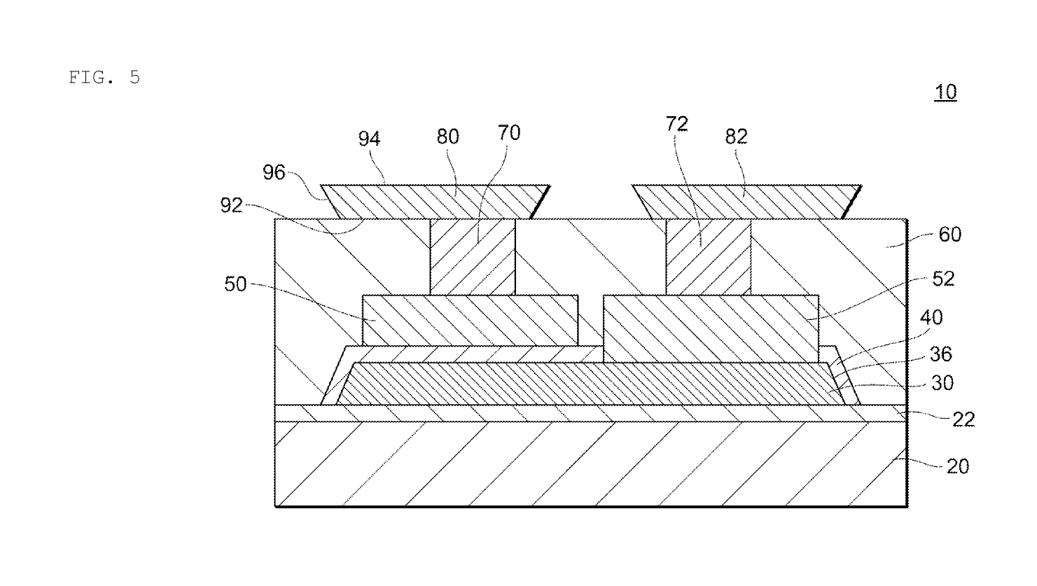

FIG. 5 is a cross-sectional view schematically illustrating a structure of the capacitor 10 according to the second embodiment. In the present embodiment, the terminal electrode 80 includes a lower surface 92 and an upper surface 94, and end surfaces 96 which are formed obliquely with respect to the lower surface 92 or the upper surface 94 to connect the lower surface 32 and the upper surface 34. That is, the end surfaces 96 of the terminal electrode 80 have such a reverse tapered shape that the area (the width in the cross section) in the plan view becomes gradually larger from the lower surface 92 to the upper surface 94.

In the present embodiment, the terminal electrode 80 has the rectangular shape in the plan view, and each of the four end surfaces 96 obliquely inclines. First of all, regarding the end surfaces 96 of the terminal electrode 80, at least the end surfaces 96 close to the region which faces the lower electrode 30 in the plan view only need to be formed obliquely with respect to the lower surface 92 or the upper surface 94. Furthermore, the end surfaces 96 may be formed in stepwise shapes.

The terminal electrode 80 according to the present embodiment is formed by, for example, the following process. That is, the metal material which forms the terminal electrode 80 is first formed on the protection film 60 and the via electrodes 70 and 72. Furthermore, when a photoresist is patterned to form a resist mask, for example, exposure conditions are adjusted by excessively exposing a negative resist and exposing a positive resist too little to form the cross section of the resist mask having a tapered shape. Furthermore, by etching the metal material using the resist mask having this tapered shape as a mask, it is possible to form the terminal electrode 80 having the reverse tapered shape (the reverse tapered shape of the resist mask).

According to the present embodiment, the end surfaces 96 of the terminal electrode 80 close to the region which faces the lower electrode 30 have the reverse tapered shape. Consequently, it is possible to further reduce the area of the facing surfaces of the lower electrode 30 and the terminal electrode 80. Consequently, it is possible to reduce the stray capacitance of the capacitor 10, and form the capacitor at a targeted capacitance value.

### 3. Third Exemplary Embodiment

Next, the capacitor 10 according to the third exemplary embodiment of the present disclosure will be described.

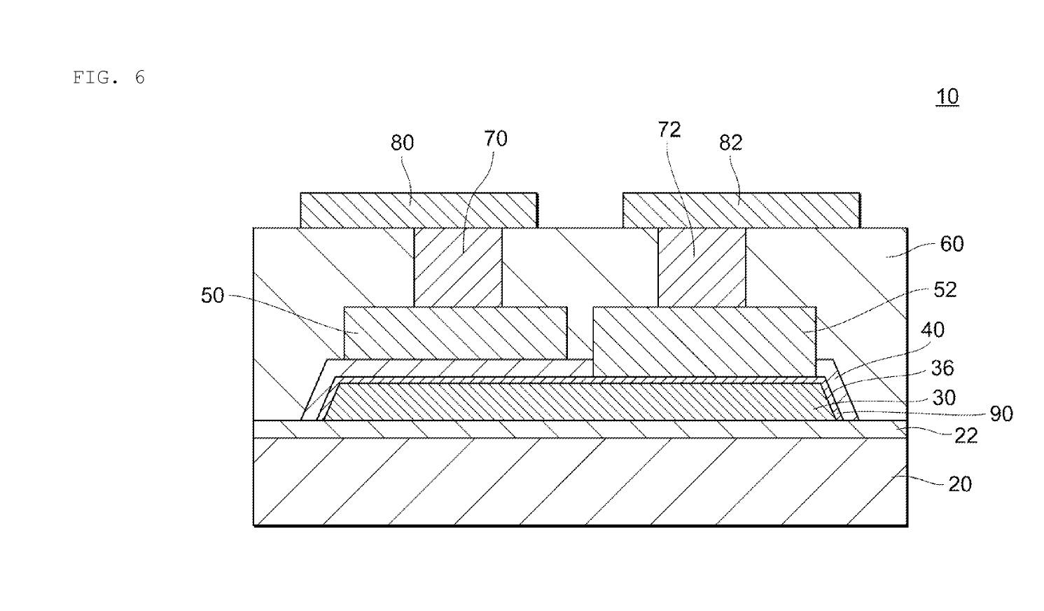

FIG. 6 is a cross-sectional view schematically illustrating a structure of the capacitor 10 according to the present exemplary embodiment. In the present embodiment, the capacitor 10 further includes a barrier film 90 between the lower electrode 30 and the dielectric film 40 (at least the upper surface 34 and the end surface 36 of the lower electrode 30). The barrier film 90 has the thickness which is, for example, 0.01 μm or more and 1 μm or less. In the present embodiment, the lower electrode 30 is formed by a material such as copper which is readily diffused in the dielectric film 40. Furthermore, the barrier film 90 is formed by a material such as a titanium, titanium tungsten, or titanium nitride which prevents the material which forms the lower electrode 30 from diffusing in the dielectric film 40.

According to the present embodiment, it is possible to prevent the material which forms the lower electrode 30 from diffusing in the dielectric film 40, and, consequently, provide the reliable capacitor.

The exemplary embodiments of the present invention have been described above.

The capacitor 10 according to one exemplary embodiment of the present disclosure includes the substrate 20, the lower electrode 30 which is formed on the substrate 20, and includes the upper surface 34, the lower surface 32 and the end surface 36 which connects the upper surface 34 and the lower surface 32, the dielectric film 40 which is formed on the lower electrode 30, the upper electrode 50 which is formed on the dielectric film 40, and the terminal electrode 80 which is connected to the upper electrode 50, and at least part of the upper surface 34 of the lower electrode 30 is formed in a region on the inner side of the periphery of the lower surface 32 of the lower electrode 30 in the plan view of the lower electrode 30 seen from the terminal electrode 80, and at least part of the end surface has the tapered shape. Consequently, it is possible to reduce the stray capacitance formed by the lower electrode 30 and the terminal electrode 80, so that only it is possible to form the capacitor at the target capacitance value.

The terminal electrode 80 includes the upper surface 94, the lower surface 92, and the end surfaces 96 which connect the upper surface 94 and the lower surface 92.At least part of the lower surface 92 of the terminal electrode 80 is formed in the region on the inner side of the periphery of the upper surface 94, and at least part of the end surface 96 has the tapered shape. Consequently, it is possible to further reduce the area of the facing surfaces of the lower electrode 30 and the terminal electrode 80. Consequently, it is possible to reduce the stray capacitance of the capacitor 10, and form the capacitor at a targeted capacitance value.

The capacitor 10 may further include the barrier film 90 which is formed between the lower electrode 30 and the dielectric film 40 as shown in FIG. 6. Consequently, it is possible to prevent the material which forms the lower electrode 30 from diffusing in the dielectric film 40, and, consequently, provide the reliable capacitor.

In addition, the above-described embodiments facilitate understanding of the present invention and are not intended to limit the present invention. The present invention can be modified/improved without departing from the gist of the invention, and include equivalents thereof. That is, design changes appropriately added to each embodiment by those skilled in the art are also incorporated in the scope of the present invention as long as the design changes include the features of the present invention. For example, the components of each embodiment, the arrangement, materials, conditions, shapes, and sizes of the components are not limited to those exemplified above and can be appropriately changed. Naturally, each embodiment is an exemplary embodiment, and configurations described in the different embodiments can be partially replaced or combined and are also included in the scope of the present invention as long as the configurations include the features of the present invention.

### DESCRIPTION OF REFERENCE SYMBOLS

10: CAPACITOR

20: SUBSTRATE

22: INSULATION FILM

30: LOWER ELECTRODE

32: LOWER SURFACE

34: UPPER SURFACE

36: END SURFACE

40: DIELECTRIC FILM

50: UPPER ELECTRODE

60: PROTECTION FILM

80: TERMINAL ELECTRODE

90: BARRIER FILM

92: LOWER SURFACE

94: UPPER SURFACE

96: END SURFACE

1. A capacitor comprising:
a substrate;
a lower electrode disposed on the substrate, the lower electrode including an upper surface, a lower surface and an end surface that connects the upper surface to the lower surface;
a dielectric film disposed on the lower electrode;
an upper electrode disposed on the dielectric film; and
a terminal electrode electrically connected to the upper electrode,
wherein at least part of a periphery of the upper surface of the lower electrode is disposed in a region inside a periphery of the lower surface of the lower electrode in a plan view of the lower electrode relative to a thickness direction of the capacitor, and
wherein at least part of the end surface that connects the upper surface to the lower surface has a tapered shape.

2. The capacitor according to claim 1,
wherein the terminal electrode includes an upper surface, a lower surface, and an end surface that connects the upper surface to the lower surface, and
wherein at least part of a periphery of the lower surface of the terminal electrode is disposed inside a periphery of the upper surface of the terminal electrode in the plan view of the terminal electrode relative to the thickness direction of the capacitor.

3. The capacitor according to claim 2, wherein at least part of the end surface of the terminal electrode has a tapered shape.

4. The capacitor according to claim 1, further comprising a barrier film disposed between the lower electrode and the dielectric film.

5. The capacitor according to claim 4, wherein the barrier film complete covers the electrode.

6. The capacitor according to claim 1, wherein the tapered shape of the end surface of the lower electrode is configured such that a cross-sectional width of the lower electrode gradually decreases from the lower surface to the upper surface.

7. The capacitor according to claim 6, wherein an angle θ between the lower surface and the end surface of the lower electrode is between 30° and 60°.

8. The capacitor according to claim 7, wherein the angle θ between the lower surface and the end surface of the lower electrode is between 40° and 50°.

9. The capacitor according to claim 1, wherein the lower surface of the lower electrode has a greater surface area than the upper surface of the lower electrode.

10. The capacitor according to claim 9, wherein the periphery of the upper surface of the lower electrode is completely disposed inside the periphery of the lower surface of the lower electrode in the plan view of the lower electrode relative to the thickness direction of the capacitor.

11. The capacitor according to claim 1, further comprising a contact electrode disposed in an opening of the dielectric film and directly coupled to the lower electrode.

12. The capacitor according to claim 11, wherein the dielectric film electrically insulates the upper electrode from the contact electrode.

13. The capacitor according to claim 12, wherein the contact electrode is electrically coupled to another terminal electrode.

14. The capacitor according to claim 1, wherein the end surface of the lower electrode overlaps the terminal electrode in the plan view of the lower electrode relative to the thickness direction of the capacitor.

15. A capacitor comprising:
a substrate;
a lower electrode disposed on the substrate, the lower electrode including an upper surface, a lower surface and a side surface that connects the upper surface to the lower surface;
an upper electrode disposed the lower electrode with a dielectric film disposed therebetween;
a terminal electrode electrically connected to the upper electrode,
wherein the side surface of the lower electrode is tapered outward from the upper surface to the lower surface of the lower electrode, such that the lower surface has a greater surface area than the upper surface.

16. The capacitor according to claim 15,
wherein the terminal electrode includes an upper surface, a lower surface, and an end surface that connects the upper surface to the lower surface,
wherein at least part of a periphery of the lower surface of the terminal electrode is disposed inside a periphery of the upper surface of the terminal electrode in the plan view of the terminal electrode relative to the thickness direction of the capacitor, and
wherein at least part of the end surface of the terminal electrode has a tapered shape.

17. The capacitor according to claim 15, further comprising a barrier film disposed between the lower electrode and the dielectric film.

18. The capacitor according to claim 15, wherein an angle θ between the lower surface and the side surface of the lower electrode is between 30° and 60°.

19. The capacitor according to claim 15, wherein a periphery of the upper surface of the lower electrode is completely disposed inside a periphery of the lower surface of the lower electrode in a plan view of the lower electrode relative to a thickness direction of the capacitor.

20. The capacitor according to claim 15, further comprising:
a contact electrode disposed in an opening of the dielectric film and directly coupled to the lower electrode,
wherein the dielectric film electrically insulates the upper electrode from the contact electrode.
